(19) United States
(12) Patent Application Publication
(10) Pub. No.: US 2007/0052037 A1
(43) Pub. Date: Mar. 8, 2007

(54) Semiconductor devices and methods of manufacture thereof

(76) Inventor: Hongfa Luan, Austin, TX (US)

Correspondence Address: SLATER & MATSIL LLP, 17950 PRESTON ROAD, SUITE 1000, DALLAS, TX, 75252, US

(21) Appl. No.: 11/434,029

(22) Filed: May 15, 2006

Related U.S. Application Data
(63) Continuation-in-part of application No. 11/219,368, filed on Sep. 2, 2005.
(63) Continuation-in-part of application No. 11/240,698, filed on Sep. 30, 2005.

(51) Int. Cl. H01L 29/94

(52) U.S. Cl. 257/369

(57) ABSTRACT

Semiconductor devices and methods of manufacture thereof are disclosed. A semiconductor device includes a first transistor and a second transistor. The first transistor comprises at least one first gate electrode including a first metal layer. The second transistor comprises at least one second gate electrode including the first metal layer. The at least one first gate electrode or the at least one second gate electrode includes a second metal layer disposed over the first metal layer.

This application is a continuation-in-part of the following co-pending U.S. patent application Ser. No. 11/219,368, filed on Sep. 2, 2005, entitled, “Transistors and Methods of Manufacture Thereof,” and Ser. No. 11/240,698, filed on Sep. 30, 2005, entitled, “Semiconductor Devices and Methods of Manufacture Thereof,” which applications are hereby incorporated herein by reference.

### TECHNICAL FIELD

The present invention relates generally to semiconductor devices, and more particularly to transistors and methods of manufacture thereof.

### BACKGROUND

Semiconductor devices are used in a variety of electronic applications, such as personal computers, cell phones, digital cameras, and other electronic equipment, as examples. Semiconductor devices are typically fabricated by sequentially depositing insulating or dielectric layers, conductive layers, and semiconductive layers of material over a semiconductor substrate, and patterning the various layers using lithography to form circuit components and elements thereon.

A transistor is an element that is utilized extensively in semiconductor devices. There may be millions of transistors on a single integrated circuit (IC), for example. A common type of transistor used in semiconductor device fabrication is a metal oxide semiconductor field effect transistor (MOSFET).

Early MOSFET processes used one type of doping to create single transistors that comprised either positive or negative channel transistors. Other more recent designs, referred to as complementary MOS (CMOS) devices, use both positive and negative channel devices, e.g., a positive channel metal oxide semiconductor (PMOS) transistor and a negative channel metal oxide semiconductor (NMOS) transistor, in complementary configurations. An NMOS device negatively charges so that the transistor is turned on or off by the movement of electrons, whereas a PMOS device involves the movement of electron vacancies. While the manufacturing of CMOS devices requires more manufacturing steps and more transistors, CMOS devices are advantageous because they utilize less power, and the devices may be made smaller and faster.

The gate dielectric for MOSFET devices has in the past typically comprised silicon dioxide, which has a dielectric constant of about 3.9. However, as devices are scaled down in size, using silicon dioxide for a gate dielectric material becomes a problem because of gate leakage current, which can degrade device performance. Therefore, there is a trend in the industry towards the development of the use of high dielectric constant (k) materials for use as the gate dielectric material in MOSFET devices. The term “high k dielectric materials” as used herein refers to dielectric materials having a dielectric constant of about 4.0 or greater, for example.

High k gate dielectric material development has been identified as one of the future challenges in the 2002 edition of International Technology Roadmap for Semiconductors (ITRS), which is incorporated herein by reference, which identifies the technological challenges and needs facing the semiconductor industry over the next 15 years. For low power logic (for portable electronic applications, for example), it is important to use devices having low leakage current, in order to extend battery life. Gate leakage current must be controlled in low power applications, as well as sub-threshold leakage, junction leakage, and band-to-band tunneling.

In electronics, the “work function” is the energy, usually measured in electron volts, needed to remove an electron from the Fermi level to a point an infinite distance away outside the surface. Work function is a material property of any material, whether the material is a conductor, semiconductor, or dielectric.

The work function of a semiconductor material can be changed by doping the semiconductor material. For example, undoped polysilicon has a work function of about 4.65 eV, whereas polysilicon doped with boron has a work function of about 5.15 eV. When used as a gate electrode, the work function of a semiconductor or conductor directly affects the threshold voltage of a transistor, for example.

In prior art CMOS devices utilizing SiO₂ as the gate dielectric material and polysilicon as the gate electrode, the work function of the polysilicon could be changed or tuned by doping the polysilicon (e.g., implanting the polysilicon with dopants). However, high k gate dielectric materials such as hafnium-based dielectric materials exhibit a Fermi-pinning effect, which is caused by the interaction of the high k gate dielectric material with the adjacent gate material. When used as a gate dielectric, some types of high k gate dielectric materials can pin or fix the work function of a polysilicon gate electrode, so that doping the polysilicon gate material does not change the work function. Thus, a symmetric Vₜ for the NMOS and PMOS transistors of a CMOS device having a high k dielectric material for the gate dielectric cannot be achieved by doping polysilicon gate material, as in SiO₂ gate dielectric CMOS devices.

The Fermi-pinning effect of high k gate dielectric materials causes a threshold voltage shift and low mobility, due to the increased charge caused by the Fermi-pinning effect. Fermi-pinning of high k gate dielectric material causes an asymmetric turn-on threshold voltage Vₜ for the transistors of a CMOS device, which is undesirable. Efforts have been made to improve the quality of high k dielectric films and resolve the Fermi-pinning problems, but the efforts have resulted in little success.

Metal would be preferred over polysilicon as a gate material, to avoid a gate depletion effect and reduce the equivalent oxide thickness (EOT) of the gate dielectric. However, it is difficult to find suitable metals for use as a gate electrode of CMOS devices, particularly for CMOS devices having high k dielectric materials for gate dielectric materials.

Thus, what are needed in the art are metal gate electrodes that have a suitable work function for CMOS device designs.

### SUMMARY OF THE INVENTION

These and other problems are generally solved or circumvented, and technical advantages are generally achieved, by preferred embodiments of the present invention, which comprise novel structures and methods of forming semiconductor devices.

In accordance with a preferred embodiment of the present invention, a semiconductor device includes a first transistor and a second transistor. The first transistor comprises at least one first gate electrode including a first metal layer. The second transistor comprises at least one second gate electrode including the first metal layer. The at least one first gate electrode or the at least one second gate electrode includes a second metal layer disposed over the first metal layer.

The foregoing has outlined rather broadly the features and technical advantages of embodiments of the present invention in order that the detailed description of the invention that follows may be better understood. Additional features and advantages of embodiments of the invention will be described hereinafter, which form the subject of the claims of the invention. It should be appreciated by those skilled in the art that the conception and specific embodiments disclosed may be readily utilized as a basis for modifying or designing other structures, such as capacitors or gated diodes, as examples, or other processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention and the advantages thereof, reference is now made to the following descriptions taken in conjunction with the accompanying drawings, in which:

FIGS. 1 through 5 show cross-sectional views of a semiconductor device at various stages of manufacturing in accordance with an embodiment of the present invention, wherein a CMOS device comprises a PMOS transistor and an NMOS transistor having different gate material thicknesses;

FIGS. 6 through 8 show cross-sectional views of another method of manufacturing a CMOS device in accordance with an embodiment of the present invention;

FIGS. 9 through 12 are graphs illustrating experimental test results of flat band voltage versus equivalent oxide thickness (EOT) at various test conditions and device configurations, showing that TiSiN is an effective material that may be used as a gate material to achieve the desired threshold voltage of the PMOS and NMOS transistors of a CMOS device by varying the thickness of the TiSiN;

FIGS. 13 and 14 show cross-sectional views of a semiconductor device at various stages of manufacturing in accordance with a preferred embodiment of the present invention, wherein a metal cap layer is used to alter the work function of a gate electrode;

FIGS. 15 and 16 show cross-sectional views of a semiconductor device at various stages of manufacturing in accordance with another preferred embodiment of the present invention, wherein two metal cap layers are used to alter the work function of two gate electrodes;

FIG. 17 shows a cross-sectional view of a semiconductor device in accordance with yet another preferred embodiment of the present invention, wherein one cap layer is left disposed over the other cap layer;

FIG. 18 shows a cross-sectional view of a semiconductor device at various stages of manufacturing in accordance with another preferred embodiment of the present invention, implemented in a FinFET device;

FIG. 19 shows a cross-sectional view an embodiment of the present invention implemented in a multiple-gate device; and

FIGS. 20 and 21 are graphs illustrating experimental test results of flat band voltage versus effective oxide thickness (EOT) at various test conditions for embodiments of the present invention, illustrating the effectiveness of the novel metal cap layers described herein in tuning the work function of gate electrodes.

Corresponding numerals and symbols in the different figures generally refer to corresponding parts unless otherwise indicated. The figures are drawn to clearly illustrate the relevant aspects of the preferred embodiments and are not necessarily drawn to scale.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

When used as a gate dielectric of a transistor, the use of high k gate dielectric materials has generally been shown to yield orders of magnitude lower gate leakage current than SiO₂ gate dielectric materials with the same effective oxide thickness (EOT). For low standby power (LSTP) and high performance (HP) applications, a high k gate dielectric material is a potential solution in the roadmap for advanced technology nodes. High k gate dielectric materials are expected to achieve the EOT, gate leakage (J_{g}), mobility, and hysteresis parameters required by LSTP applications.

However, Vₜ controllability with high k gate dielectric materials is proving challenging. For example, in order for high k gate dielectric materials to be useful in CMOS applications, a CMOS device requires a symmetrical Vₜₙ and Vₜₚ (e.g., Vₜₙ=+0.3 V and Vₜₚ=−0.3 V).

Attempts to use high k dielectric materials as a gate dielectric material have been problematic. In particular, attempts have been made to use HfO₂, which is a high k dielectric material having a dielectric constant of about 25, as a gate dielectric for the PMOS and NMOS FETs of a CMOS device. If polysilicon is used as a gate material, the work function of the polysilicon gate using a HfO₂ gate dielectric has been found to be pinned, as a result of Fermi-pinning, at a point close to the conduction band of polysilicon, causing the polysilicon gate to function as N type polysilicon, even for a polysilicon gate doped with P type dopant, for the PMOS device. This has been found to cause asymmetric threshold voltages Vₜ for the PMOS and NMOS transistors of CMOS devices. Polysilicon used as a material for a gate electrode will also cause a poly depletion problem, for example.

Because the Fermi-pinning effect makes polysilicon incompatible for use as a gate material (e.g., used directly adjacent the gate dielectric), it is desirable to find a metal that may be used for PMOS and NMOS devices as a gate material.

It has been found that conventional bulk single-gate planar MOSFET devices probably cannot achieve the requested performance for future technology nodes of 45 nm and beyond. The classic bulk device concept is based on a complex three-dimensional doping profile, including channel implants, source/drain region implants, lightly doped drain (LDD) extension implants, and pocket/halo implants, which is not scalable further (e.g., cannot be further reduced in size), because of an increase in dopant fluctuations and stronger parasitic short channel effects, due to lack of potential control in the channel region and the deep substrate. Therefore, one proposed new design concept is a fully depleted planar SOI MOSFET device, which is formed on an SOI substrate.

For classical bulk MOSFET devices, it is expected that conventional high performance CMOS devices will require both high k dielectric materials and metal gate electrodes to eliminate poly depletion, as devices scale down to the 1 nm equivalent oxide thickness (EOT) (e.g., for the gate material). The potential metal gate materials must exhibit band-edge work functions, exhibit work function stability as a function of temperature, and maintain thermal stability with the underlying dielectric. The semiconductor industry is struggling to find adequate n-type and p-type metal materials to use as gate electrodes for the conventional bulk MOSFET, wherein the work function of adequate n-type and p-type metal would be about 4.1 eV for n-type and 5.2 eV for p-type.

Next, some definitions of terms used herein will next be described. The term, “mid-gap gate work function” is defined herein to be around 4.65 eV, because this is the “mid” or middle value of the work functions of n-doped polycrystalline silicon with a work function of approximately 4.1 eV, and p-doped poly-crystalline silicon having a work function of approximately 5.2 eV, as examples. The difference between 4.1 eV and 5.2 eV is the energy gap of 1.1 eV between the valence band and the conduction band of silicon, for example. The term, “near mid-gap” as used herein is defined to be a work function of close to about 4.65 eV; e.g., 4.45 eV is a near mid-gap work function for an NMOS transistor, and 4.85 eV is a near-mid-gap work function for a PMOS transistor of a CMOS device.

In U.S. patent application Ser. No. 11/219,368, filed on Sep. 2, 2005, entitled, “Transistors and Methods of Manufacture Thereof,” which is incorporated herein by reference, metals that are useful as a gate material in a CMOS transistor, for both an NMOS transistor and a PMOS transistor are described. In one embodiment, the gate material preferably comprises TiSiN. In other embodiments, the gate material preferably comprises TaN or TiN. The work function of the NMOS transistor and PMOS transistor is adjusted by tuning or adjusting the thickness of the gate material. Rather than implementing two different gate materials, the work functions are defined or adjusted by different layer thicknesses of the gate layer using layer deposition and etch-back processes.

The present invention will next be described with respect to preferred embodiments in a specific context, namely implemented in CMOS devices comprising transistors having single and multiple gates. Embodiments of the present invention may also be applied, however, to other semiconductor device applications where two or more transistors are utilized, as examples. Note that in the drawings shown, only one CMOS device is shown; however, there may be many transistors formed on a semiconductor workpiece during each of the manufacturing processes described herein. The term “gate” and “gate electrode” refer to the gate of a transistor, and these terms are used interchangeably herein.

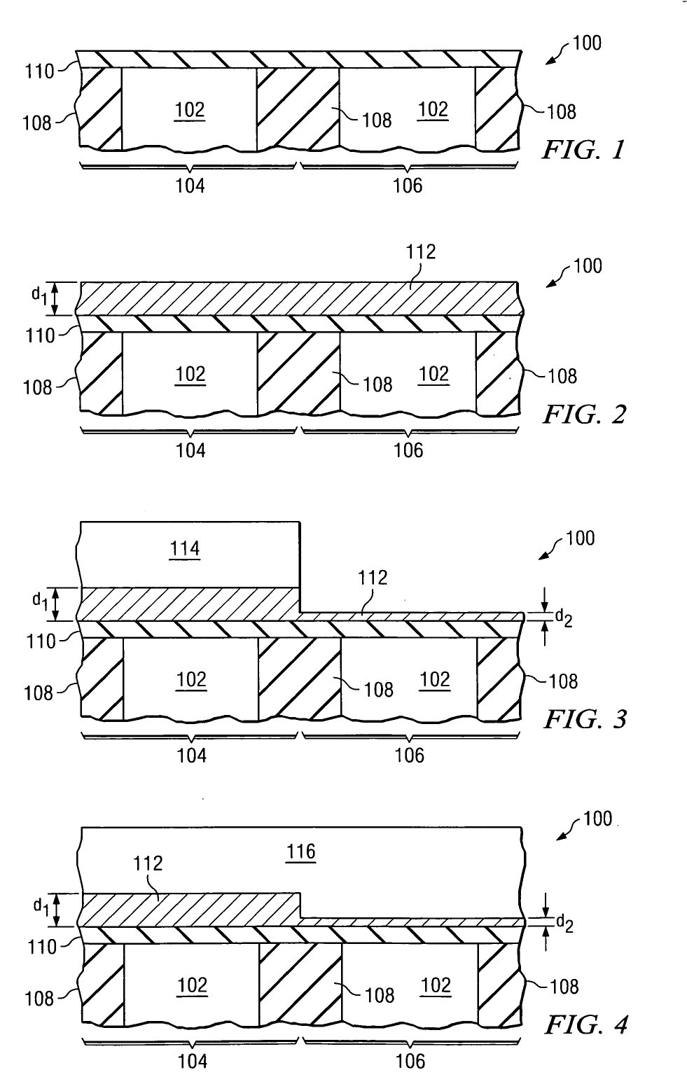

FIGS. 1 through 5 show cross-sectional views of a semiconductor device 100 at various stages of manufacturing in accordance with a preferred embodiment of the present invention. With reference now to FIG. 1, there is shown a semiconductor device 100 in a cross-sectional view including a workpiece 102. The workpiece 102 may include a semiconductor substrate comprising silicon or other semiconductive materials covered by an insulating layer, for example. The workpiece 102 may also include other active components or circuits, not shown. The workpiece 102 may comprise silicon oxide over single-crystal silicon, for example. The workpiece 102 may include other conductive layers or other semiconductor elements, e.g., transistors, diodes, etc. Compound semiconductors, GaAs, InP, Si/Ge, or SiC, as examples, may be used in place of silicon. In one embodiment, the workpiece 102 preferably comprises a silicon-on-insulator (SOI) substrate, including a first layer of semiconductive material (not shown), a buried insulating layer or buried oxide layer (also not shown) disposed over the first layer of semiconductive material, and a second layer of semiconductive material disposed over the buried insulating layer, for example.

The workpiece 102 may be doped with P type dopants and N type dopants, e.g., to form a P well and N well, respectively (not shown). For example, a PMOS device is typically implanted with N type dopants, e.g., in a first region 104, and an NMOS device is typically implanted with P type dopants, e.g., in a second region 106. The workpiece 102 may be cleaned using a pre-gate cleaning process to remove contaminants or native oxide from the top surface of the workpiece 102. The pre-gate treatment may comprise a HF, HCl, or an ozone based cleaning treatment, as examples, although the pre-gate treatment may alternatively comprise other chemistries.

A shallow trench isolation (STI) region 108 is formed between what will be active areas in the first and second regions 104 and 106 of the workpiece 102. If the workpiece 102 comprises an SOI substrate 102, the shallow trench isolation region 108 may be formed by patterning the second layer of semiconductive material of the workpiece 102, and filling the patterned second layer of semiconductive material with an insulating material such as silicon dioxide, although other materials may be used, for example. The STI region 108 may be formed in the second layer of semiconductive material of the workpiece, and the etch process for the STI region 108 trenches may be adapted to stop on the buried insulating layer of the SOI substrate 102, for example.

A gate dielectric material 110 is formed over the workpiece 102. The gate dielectric material 110 preferably comprises a high k dielectric material having a dielectric constant of about 4.0 or greater, in one embodiment, for example. The gate dielectric material 110 may alternatively comprise a dielectric material such as SiO₂, for example. The gate dielectric material 110 preferably comprises HfO₂, HfSiO_{X}, Al₂O₃, ZrO₂, ZrSiOₓ, Ta₂O₅, La₂O₃, nitrides thereof, SiₓN_{y}, SiON, HfAlOₓ, HfAlOₓN_{1-x-y}, ZrAlOₓ, ZrAlOₓN_{y}, SiAlOₓ, SiAlOₓN_{1-x-y}, HfSiAlOₓ, HfSiAlOₓN_{y}, ZrSiAlOₓ, ZrSiAlOₓN_{y}, SiO₂, combinations thereof, or multiple layers thereof, as examples, although alternatively, the gate dielectric material 110 may comprise other high k dielectric materials or other dielectric materials.

The gate dielectric material 110 may comprise a single layer of material, or alternatively, the gate dielectric material 110 may comprise two or more layers. In one embodiment, one or more of these materials can be included in the gate dielectric material 110 in different combinations or in stacked layers. The gate dielectric material 110 may be formed by chemical vapor deposition (CVD), atomic layer deposition (ALD), metal organic chemical vapor deposition (MOCVD), physical vapor deposition (PVD), or jet vapor deposition (JVD), as examples, although alternatively, the gate dielectric material 110 may be formed using other techniques.

The gate dielectric material 110 preferably comprises a thickness of about 50 Angstroms or less in one embodiment, although alternatively, the gate dielectric material 110 may comprise other dimensions, such as about 80 Angstroms or less, as an example. The gate dielectric material 110 preferably comprises about 20 to 30 Angstroms, in one embodiment, for example.

In one embodiment, the gate dielectric material 110 preferably comprises about 10 Angstroms of SiO₂ disposed over the workpiece 102 and about 30 Angstroms of HfSiO₂ disposed over the SiO₂. Alternatively, the gate dielectric material 110 may comprise other materials, combinations of materials, and thicknesses, as examples.

Next, a gate material 112 is formed over the gate dielectric material 110, as shown in FIG. 2. The gate material 112 preferably comprises a layer of TiSiN, in accordance with some embodiments of the present invention. The gate material 112 alternatively may comprise other metals in which the work function of the metal may be adjusted, tuned, or altered by varying the thickness of the metal, for example, such as TiN or TaN, as examples, although alternatively, the gate material 112 may comprise other metal materials. The gate material 112 is preferably deposited using MOCVD in one embodiment, although alternatively, the gate material 112 may be formed by ALD, PVD, or other deposition techniques, as examples.

The gate material 112 preferably comprises a first thickness d₁. The first thickness d₁ preferably comprises a thickness of about 500 Angstroms or less, and more preferably comprises a thickness of about 200 Angstroms in one embodiment, as examples, although alternatively, the first thickness d₁ may comprise other dimensions.

Next, a layer of photoresist 114 is deposited over the gate material 112, as shown in FIG. 3. The layer of photoresist 114 is patterned using lithography techniques, to remove the layer of photoresist 114 from over the second region 106 of the workpiece 102. At least a portion of the gate material 112 is etched away using an etch process, also shown in FIG. 3. The etch process may comprise a timed etch process and/or a wet etch process, as examples, although alternatively, other etch processes may be used. The layer of photoresist 114 protects the gate material 112 during the etch process, for example.

The gate material 112 in the second region 106 after the etch process preferably comprises a second thickness d₂, as shown in FIG. 3. The second thickness d₂ is preferably less than the first thickness d₁, for example, and even more preferably, the first thickness d₁ is greater than the second thickness d₂ by at least 50 Angstroms or more, for example. The second thickness d₂ preferably comprises about 100 Angstroms or less, and more preferably comprises a thickness of about 25 Angstroms, as examples, although alternatively, the second thickness d₂ may comprise other dimensions, for example. The layer of photoresist 114 is then removed.

Next, optionally, a semiconductive material 116 is deposited over the gate material 112, as shown in FIG. 4. The semiconductive material 116 comprises part of a gate electrode of the transistors formed in the first region 104 and second region 106, for example. The semiconductive material 116 preferably comprises about 1,000 Angstroms of polysilicon, for example, although alternatively, the semiconductive material 116 may comprise other dimensions and materials.

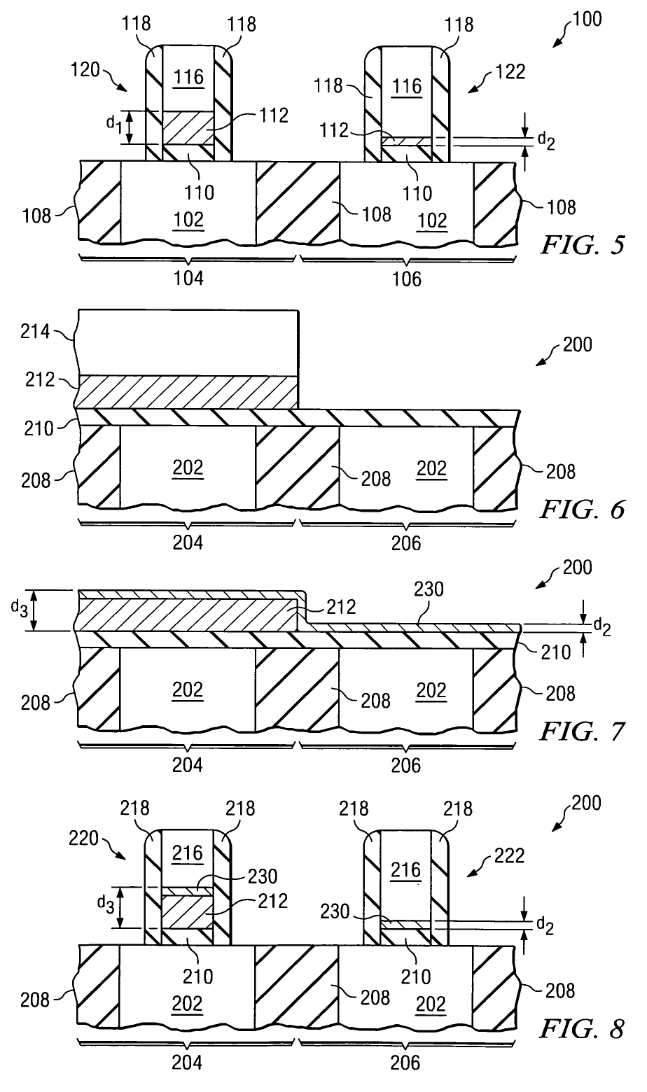

Next, the gate materials 116 and 112 and the gate dielectric material 110 are patterned using lithography to form a gate 112/116 and a gate dielectric 110 of a PMOS transistor 120 in the first region 104 and an NMOS transistor 122 in the second region 106, as shown in FIG. 5. For example, a layer of photoresist (not shown) may be deposited over the gate material semiconductive material 116, and the photoresist may be patterned using a lithography mask and an exposure process. The photoresist is developed, and the photoresist is used as a mask while portions of the gate materials 116 and 112 and gate dielectric material 110 are etched away.

The workpiece 102 may be implanted with dopants to form source and drain regions (not shown) proximate the gate dielectric 110. Spacers 118 comprising an insulating material such as an oxide, nitride, or combinations thereof, may be formed over the sidewalls of the gate 112/116 and gate dielectric 110, as shown in FIG. 5.

Processing of the semiconductor device 100 is then continued, such as forming insulating and conductive layers over the transistors 120 and 122, as examples (not shown). For example, one or more insulating materials (not shown) may be deposited over the transistors 120 and 122, and contacts may be formed in the insulating materials in order to make electrical contact with the gate 112/116, and source and/or drain regions. Additional metallization and insulating layers may be formed and patterned over the top surface of the insulating material and contacts. A passivation layer (not shown) may be deposited over the insulating layers or the transistors 120 and 122. Bond pads (also not shown) may be formed over contacts, and a plurality of the semiconductor devices 100 may then be singulated or separated into individual die. The bond pads may be connected to leads of an integrated circuit package (not shown) or other die, for example, in order to provide electrical contact to the transistors 120 and 122 of the semiconductor device 100.

The transistors 120 and 122 preferably comprise a PMOS transistor 120 and an NMOS transistor 122, in one embodiment. The metal layer 112 is preferably thicker in the PMOS transistor 120 than in the NMOS transistor 122, in accordance with embodiments of the present invention. The first thickness d, of the metal layer 112 in the PMOS transistor 120 causes the gate material 112 to have a work function of about 4.85 eV, in one embodiment. The second thickness d₂ of the metal layer 112 in the NMOS transistor 122 causes the gate material 112 to have a work function of about 4.45 eV, in one embodiment. The transistors 120 and 122 preferably have substantially symmetric threshold voltages of about +0.3 and −0.3 V, respectively, as examples, in one embodiment, although the threshold voltages may alternatively comprise other voltage levels.

Another preferred embodiment of the present invention is shown in a cross-sectional view in FIGS. 6 through 8 at various stages of manufacturing. Like numerals are used for the elements in FIGS. 6 through 8 as were used in FIGS. 1 through 5, and to avoid repetition, the descriptions of the elements and formation thereof are not repeated herein.

In this embodiment, during the etch process to reduce the thickness of the metal layer 212 in the second region 206, all of the metal layer 212 is removed in the second region 206, as shown in FIG. 6. Then, another metal layer 230 is deposited over the first metal layer 212 in the first region 204, and over the exposed gate dielectric 210 in the second region 206, as shown in FIG. 7. Processing of the semiconductor device 200 is then continued as described with reference to FIG. 5, leaving the structure shown in FIG. 8.

The first metal layer 212 as deposited preferably comprises a thickness of about 200 Angstroms, in one embodiment. The second metal layer 230 preferably comprises a thickness of about 25 Angstroms. The thickness d₃ of the metal portion of the gate 212/230 of the PMOS transistor 220 in the first region 204 preferably comprises about 225 Angstroms, for example. The thickness d₂ of the metal portion of the gate 230 of the NMOS transistor 222 in the second region 206 preferably comprises about 25 Angstroms, for example. However, alternatively, the metal layers 212 and 230 may comprise other dimensions, for example.

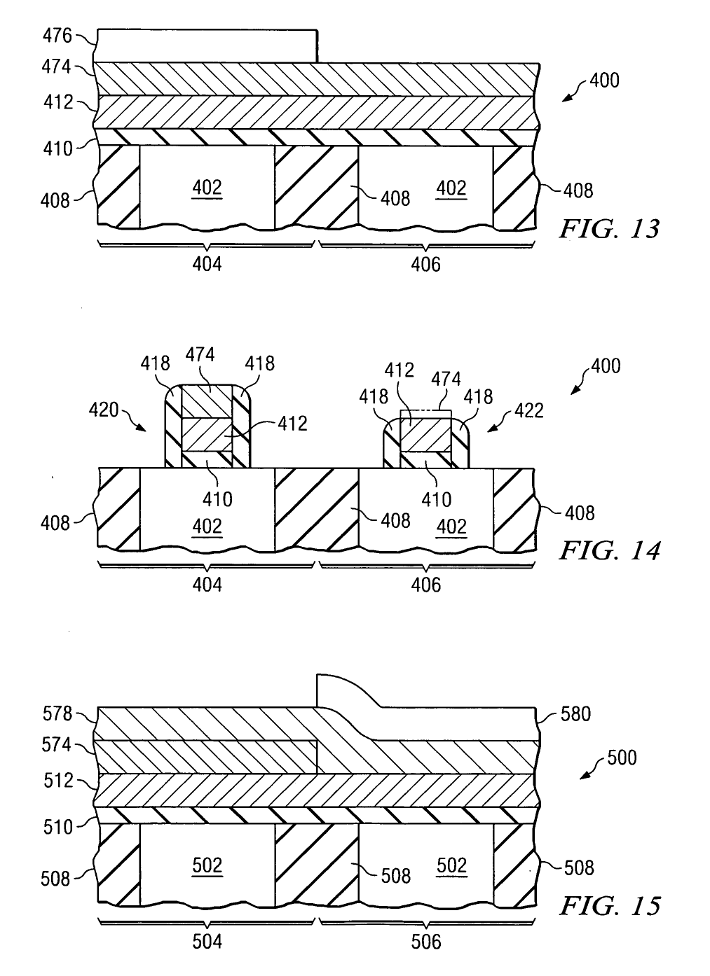

In some embodiments, the second metal layer 230 preferably comprises the same material as the first metal layer 212. However, in other embodiments, the second metal layer 230 preferably comprises a different material than the first metal layer 212, to be described further herein with reference to FIGS. 13 through 21.

Referring again to FIG. 8, note that after depositing the layer of semiconductive material 216, the layer of semiconductive material 216 may be doped using an implantation process with dopants. For example, if the transistor 220 comprises a PMOS transistor, the semiconductive material 216 is preferably implanted with a P type dopant. Alternatively, the semiconductive material 216 may be implanted with an N type dopant, for example. However, the semiconductive material 216 may alternatively be implanted with other types of dopants, or may not be doped at all.

After implanting the semiconductive material 216 with a dopant, the layer of semiconductive material 216, the gate materials 230 and 212, and the gate dielectric material 210 are patterned, and processing of the semiconductor device 200 is then continued as described with reference to FIGS. 1 through 5, as shown in FIG. 8.

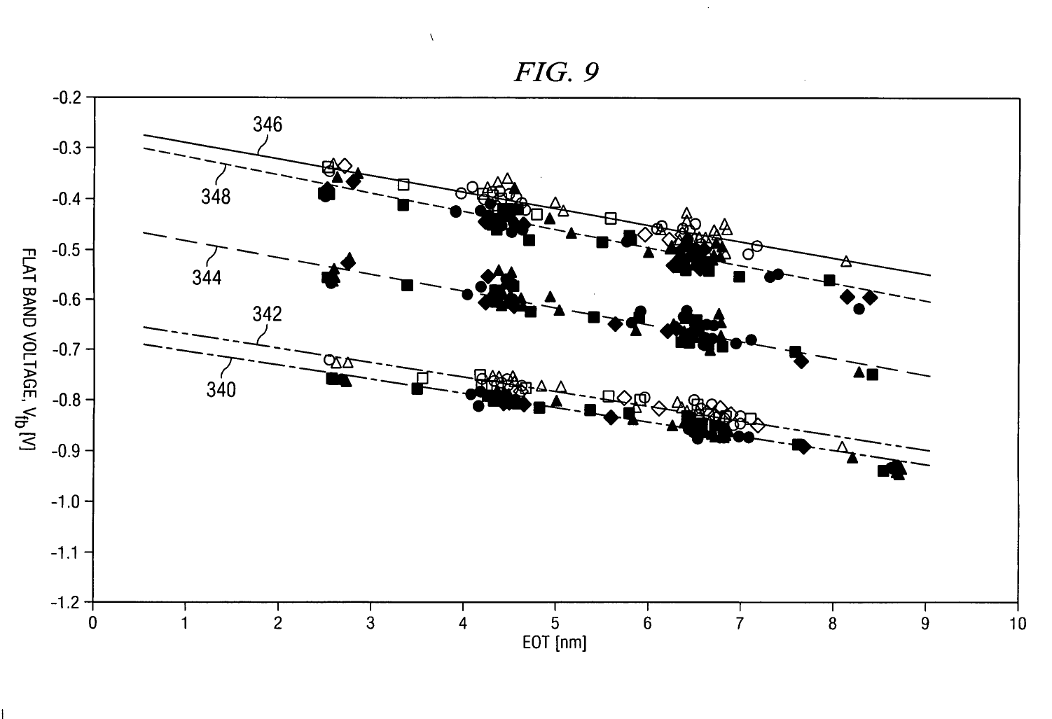

FIGS. 9 through 12 are graphs illustrating experimental test results of flat band voltage (V_{fb}) in volts (V) versus the equivalent oxide thickness (EOT) at various test conditions and device configurations for NMOS devices, showing that TiSiN is an effective material that may be used as a gate material to achieve the desired threshold voltage of the PMOS and NMOS transistors of a CMOS device, by varying the thickness of the TiSiN.

For example, referring next to FIG. 9, a graph of test results of a semiconductor device 100 is shown, wherein the metal gate material comprised TiSiN, and the gate dielectric of both the NMOS and PMOS device comprises about 20 Angstroms of HfOₓ. Graph 340 shows test results, in flat band voltage vs. EOT (in nm) for N_{f}, which indicates the fixed charge at the interface between the dielectric film and substrate, of about 5.93×10¹¹/cm², and having a work function of about 4.4 eV, for a metal layer of about 25 Angstroms. Graph 342 shows test results for an N_{f} of about 6.06×10¹¹/cm², and having a work function of about 4.43 eV, for a metal layer of about 50 Angstroms. Graph 344 shows test results of about 7.17×10¹¹/cm², and having a work function of about 4.63 eV, for a metal layer of about 100 Angstroms. Graph 346 shows test results of about 6.82×10¹¹/cm², and having a work function of about 4.81 eV, for a metal layer of about 200 Angstroms. Graph 348 shows test results of about 7.54×10¹¹/cm², and having a work function of about 4.79 eV, for a metal layer of about 400 Angstroms. Note that at about 200 Angstroms, the work function of TiSiN becomes saturated, e.g., increasing the TiSiN thickness greater than 200 Angstroms to 400 Angstroms does not further increase the work function.

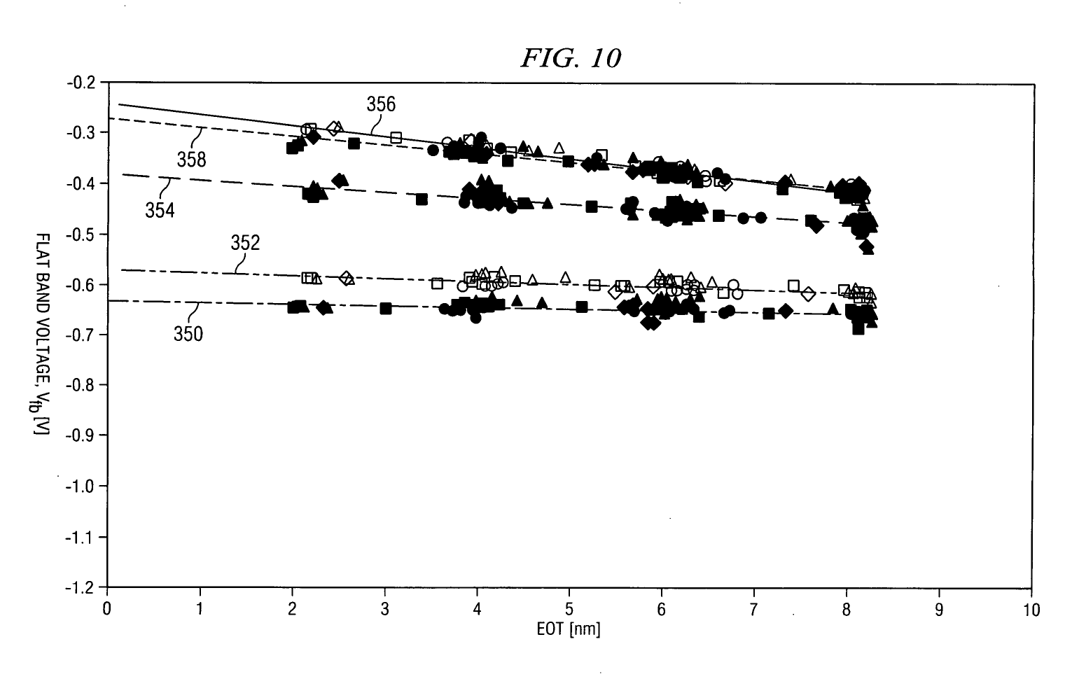

FIG. 10 shows a similar plot for an NMOS device having a gate comprised of TiSiN and a gate dielectric of about 30 Angstroms of HfSiOₓ. Graph 350 shows test results, in V_{fb} vs. EOT, for an N_{f} of about 5.49×10¹⁰/cm², and having a work function of about 4.44 eV, for a metal layer of about 25 Angstroms. Graph 352 shows test results for an N_{f} of about 1.16×11¹¹/cm², and having a work function of about 4.5 eV, for a metal layer of about 50 Angstroms. Graph 354 shows test results of about 2.48×10¹¹/cm², and having a work function of about 4.69 eV, for a metal layer of about 100 Angstroms. Graph 356 shows test results for an N_{f} of about 4.58×10¹¹/cm², and having a work function of about 4.83 eV, for a metal layer of about 200 Angstroms. Graph 358 shows test results, for an N_{f} of about 3.63×10¹¹/cm², and having a work function of about 4.8 eV, for a metal layer of about 400 Angstroms. Again, the TiSiN work function becomes saturated at a thickness of about 200 Angstroms.

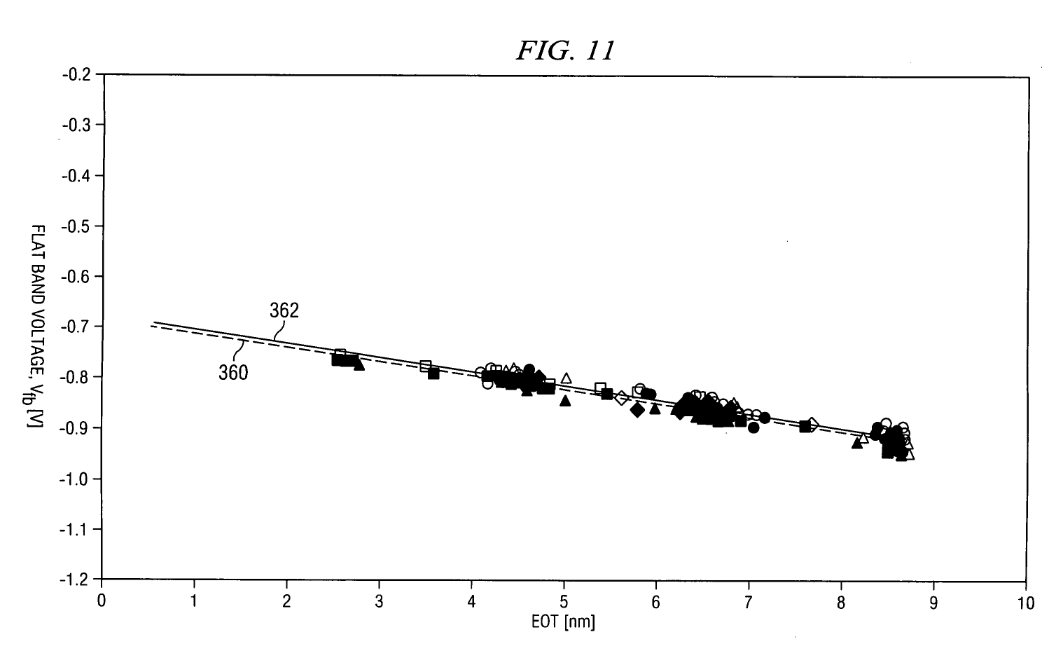

FIG. 11 illustrates a comparison of the use of an n-poly cap with a p-poly cap (e.g., the gate electrodes of the PMOS and NMOS transistor include the optional semiconductive material 116 or 216), wherein the poly caps comprises a thickness of about 1,000 Angstroms, in a TiSiN over a 20 Angstroms thick HfOₓ structure. At 360, the test results for p-poly disposed over about 25 Angstroms of TiSiN over 20 Angstroms of HfOₓ is shown, at an N_{f} of 5.95×10¹¹/cm² and a work function of 4.39 eV. At 362, the test results for n-poly disposed over 25 Angstroms of TiSiN disposed over 20 Angstroms of HfOₓ is shown, at an N_{f} of 5.93×10¹¹/cm² and a work function of 4.4 eV. The identical work function from both the n-poly cap and p-poly cap gate electrodes indicates that even though the TiSiN layer is thin (25 Angstroms), the film is continuous and sufficient to control the work function. The term “continuous” refers to the finding by the inventors of the present invention that although 25 Angstroms is extremely thin, TiSiN formed at a thickness of 25 Angstroms was not found to form islands of material, as can occur with some thin films; rather, advantageously, the 25 Angstrom thick layer of TiSiN was found to form a thin layer of material having a continuous coverage of the underlying material layer. Thus, such a thin layer of TiSiN is useful as a gate electrode material of a transistor, for example.

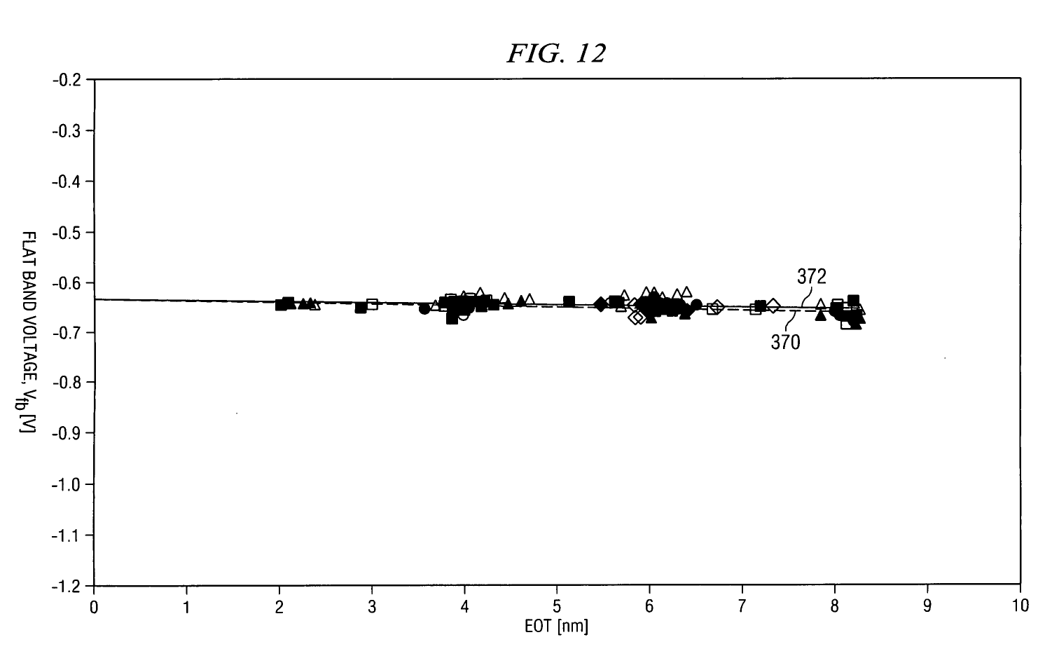

FIG. 12 illustrates a comparison of the use of an n-poly cap with a p-poly cap having a thickness of about 1,000 Angstroms, in a TiSiN over an HfSiOₓ structure. At 370, the test results for p-poly disposed over a 25 Angstroms thick structure of TiSiN/HfSiOₓ is shown, at an N_{f} of 6.6495×10¹¹/cm² and a work function of 4.44 eV. At 372, the test results for n-poly disposed over a 25 Angstroms thick structure of TiSiN/HfSiOₓ is shown, at an N_{f} of 5.49×10¹⁰/cm² and a work function of 4.44 eV. Again, a 25 Angstrom thickness of the TiSiN was found to be continuous and sufficient to control the work function, advantageously.

The results shown in FIG. 9 through 12 show that the work function is reliable for the various TiSiN thicknesses tested. In accordance with the experimental results of the novel invention described herein, the work function of a 25 Angstroms thick layer of TiSiN has been found to be about 4.44 eV disposed on a dielectric layer of HfSiOₓ, and about 4.40 eV disposed on a dielectric layer of HfOₓ. The work function of a 200 Angstroms thick layer of TiSiN has been found to be about 4.83 eV disposed on a dielectric layer of HfSiOₓ, and about 4.81 eV disposed on a dielectric layer of HfOₓ. Advantageously, the work function data show that these TiSiN material layers may be implemented in CMOS devices to achieve the desired threshold voltage of the CMOS devices. Preferably, about 25 Angstroms of TiSiN is used as a gate electrode of an NMOS device, and about 200 Angstroms of TiSiN is used as a gate electrode of a PMOS device, if the gate dielectric comprises a H_{f}-based gate dielectric, for example, to achieve a symmetric Vₜ for the CMOS device. TaN and TiN have also been found to have an adjustable work function, based on the film thickness.

In the embodiments of the invention shown and described with reference to FIGS. 1 through 12, the material of the gate electrodes 112, 212, and 230 of the transistors 120 and 122, and 220 and 222, preferably comprise the same material, and the work function of the gate electrodes of the transistors 120, 122, 220, and 222, is tuned or altered to the desired amount using the thickness of the gate electrodes 112, 212, or 212/230. In other embodiments of the invention, the work function of gate electrodes of transistors is tuned using a cap layer.

FIGS. 13 and 14 show cross-sectional views of a semiconductor device at various stages of manufacturing in accordance with a preferred embodiment of the present invention. In this embodiment, the work function is altered or adjusted using a cap layer on one or both of the gate electrodes, wherein the cap layer comprises a different material than an underlying metal layer.

To form the semiconductor device 400, a gate dielectric material 410 is formed over the workpiece 402 that may have STI regions 408 formed therein, as shown in FIG. 13. The gate dielectric material 410 preferably comprises a hafnium-based dielectric, HfO₂, HfSiO_{X}, Al₂O₃, ZrO₂, ZrSiO_{X}, Ta₂O₅, La₂O₃, nitrides thereof, SiₓN_{y}, SiON, HfAlOₓ, HfAlOₓN_{1-x-y}, ZrAlOₓ, ZrAlOₓN_{y}, SiAlOₓ, SiAlOₓN_{1-x-y}, HfSiAlOₓ, HfSiAlOₓN_{y}, ZrSiAlOₓ, ZrSiAlOₓN_{y}, combinations thereof, combinations thereof with SiO₂, or SiO₂, as examples, although alternatively, the gate dielectric material 410 may comprise other materials. The gate dielectric material 410 may comprise a high k dielectric material having a dielectric constant of about 4.0 or greater, for example. The gate dielectric material 410 preferably comprises a thickness of about 50 Angstroms or less in one embodiment, although alternatively, the gate dielectric material 410 may comprise other dimensions.

In this embodiment, after the gate dielectric 410 is formed over the workpiece 402, a gate electrode material comprising a first metal layer 412 is deposited or formed over the gate dielectric material 410, as shown in FIG. 13. The first metal layer 412 preferably comprises a metal that may be used to establish or set the work function of transistors to be formed (e.g., transistors 420 and 422 shown in FIG. 14). The first metal layer 412 preferably comprises TiSiN, in one embodiment, which is a material that has a variable work function, depending on the thickness, and also depending on the type of cap material disposed thereon, for example. The first metal layer 412 may alternatively comprise TaN or TiN, in other preferred embodiments, as examples. Alternatively, the first metal layer 412 may comprise TiSiN, TiN, TaN, Ta, Ru, HfN, W, Al, RuTa, TaSiN, NiSiₓ, CoSiₓ, TiSiₓ, Ir, Y, Pt, Ti, PtTi, Pd, Re, Rh, borides, phosphides, or antimonides of Ti, Hf, Zr, TiAlN, Mo, MoN, ZrSiN, ZrN, HfN, HfSiN, WN, Ni, Pr, VN, TiW, partially silicided materials thereof, fully silicided materials thereof, and/or combinations thereof, as examples, although alternatively, the first metal layer 412 may comprise other materials.

The first metal layer 412 preferably comprises a thickness of about 200 Angstroms or less, and more preferably comprises a thickness of about 25 to 50 Angstroms in some embodiments, although alternatively, the first metal layer 412 may comprise other dimensions, for example. In a preferred embodiment, the first metal layer 412 comprises a thickness of about 25 Angstroms, as an example.

Then, a second metal layer 474 is deposited or formed over the first metal layer 412, as shown in FIG. 13. The second metal layer 474 is also referred to herein as a cap layer or as a first cap layer. The second metal layer 474 preferably comprises a material that is different than the material of the first metal layer 412. The second metal layer 474 preferably comprises a material that is adapted to alter the work function of the metal stack of the transistors 420 and 422. For example, the second metal layer 474 preferably comprises a material that is adapted to alter the work function of the metal stack of the transistors 420 and 422 that is established by the first metal layer 412 prior to the deposition of the second metal layer 474. Thus, in this embodiment, both the first metal layer 412 and the second metal layer 474 establish the work function of the metal stack of the transistors 420 and 422.

In one embodiment, the second metal layer 474 preferably comprises TaCN. In another embodiment, the second metal layer 474 preferably comprises TiN. In other embodiments, the second metal layer 474 may comprise other metals adapted to alter the work function of the metal stack of the transistors, which sets the threshold voltage of the transistors 420 and 422, such as TiSiN, TiN, TaCN, TaN, Ta, Ru, HfN, W, Al, RuTa, TaSiN, NiSiₓ, CoSiₓ, TiSiₓ, Ir, Y, Pt, Ti, PtTi, Pd, Re, Rh, borides, phosphides, or antimonides of Ti, Hf, Zr, TiAlN, Mo, MoN, ZrSiN, ZrN, HfN, HfSiN, WN, Ni, Pr, VN, TiW, partially silicided materials thereof, fully silicided materials thereof, and/or combinations thereof, as examples, although alternatively, the second metal layer 474 may comprise other materials.

The second metal layer 474 preferably comprises a thickness of about 200 Angstroms or less, and more preferably comprises a thickness of about 50 to 100 Angstroms in some embodiments, although alternatively, the second metal layer 474 may comprise other dimensions, for example. In a preferred embodiment, the second metal layer 474 comprises about 100 Angstroms, as an example.

The second metal layer 474 is preferably formed over one of the transistors 420 but not over the other transistor 422, as shown in FIG. 14. To accomplish this, a layer of photosensitive material 476 such as photoresist may be deposited over the second metal layer 474, as shown in FIG. 13. The layer of photosensitive material 476 is patterned, e.g., using lithography, and the layer of photosensitive material 476 is removed in region 406 of the workpiece 402. The layer of photosensitive material 476 is then used as a mask while portions of the second metal layer 474 are removed in region 406, e.g., using an etch process.

The manufacturing process is then continued to form transistors 420 and 422, as shown in FIG. 14. For example, the second metal layer 474, first metal layer 412, and gate dielectric material 410 are patterned using lithography, and sidewall spacers 418 are formed over the sidewalls of the gate dielectric 410 and gate electrode 474/412 of transistor 420, and over the sidewalls of the gate dielectric 410 and gate electrode 412 of transistor 422, as shown. Advantageously, the gate electrode of transistor 420 comprises the first metal layer 412 and the second metal layer 474, whereas the gate electrode of transistor 422 comprises only the first metal layer 412. Thus, the second metal layer 474 functions as a cap layer that is used to tune or alter the work function of the gate electrode of at least one of the transistors 420 and/or 422, in this embodiment. For example, because the gate electrode 474/412 of transistor 420 includes the second metal layer 474, the second metal layer 474 affects the work function of the gate electrode 474/412, which alters the threshold voltage of the transistor 420.

Note that the second metal layer 474 may also be formed over transistor 422, as shown in phantom in FIG. 14. In this embodiment, the second metal layer 474 may be deposited over both regions 404 and 406, and the second metal layer 474 may be thinned in region 406, e.g., by a partial etch of the second metal layer 474 in region 406, for example. Thus, the thickness of the cap layers 474 of the transistors 420 and 422 is used to tune the work function of the gate electrodes of the transistors 420 and 422 in this embodiment.

In yet another embodiment, the thickness of the first metal layer 412 may also be used as another variable, in combination with the use of the second metal layer 474 on transistor 420 and/or 422, wherein the thickness of the first metal layer 412 and the presence and/or the thickness of the second metal layer 474 each comprise means of tuning or altering the work function of the gate electrodes of the transistors 420 and 422. For example, the first metal layer 412 may comprise a first thickness in region 404 and a second thickness in region 404, wherein the second thickness is different than the first thickness, as shown in FIGS. 1-8. Likewise, the second metal layer 474 may comprise a third thickness in region 404 and a fourth thickness in region 404, wherein the fourth thickness is different than the third thickness.

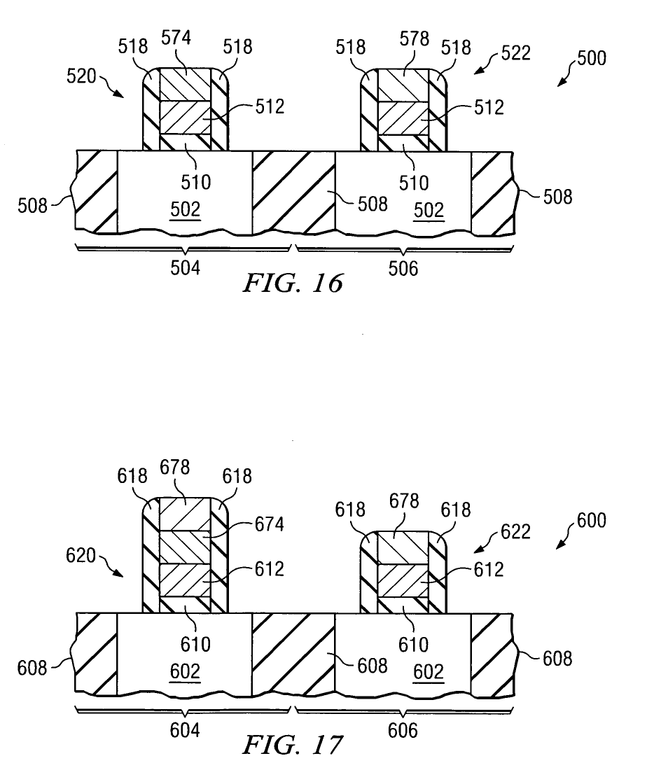

FIGS. 15 and 16 show cross-sectional views of a semiconductor device at various stages of manufacturing in accordance with another preferred embodiment of the present invention. In this embodiment, another metal layer, e.g., a third metal layer 578 is also used to tune or alter the work function of the gate electrode of the transistor 522. Like numerals are used for the elements in FIGS. 15 and 16 as were used for the elements in FIGS. 13 and 14, and to avoid repetition, the materials and thicknesses for the various elements are not described again herein for FIGS. 15 and 16.

In this embodiment, after forming the first metal layer 512 over both regions 504 and 506, and after forming the second metal layer 574 in region 504, the third metal layer 578 is formed in region 506. This may be accomplished by depositing the third metal layer 578 over the second metal layer 574 in region 504 and over the first metal layer 512 in region 506, as shown in FIG. 15. A layer of photosensitive material 580 is then used as a mask while portions of the third metal layer 574 are removed in region 504. Alternatively, the third metal layer 578 may be left remaining over the second metal layer 574 in region 504, either in its entirety as deposited, or thinned using a partial etch process, as shown in FIG. 17. The third metal layer 578, second metal layer 574, first metal layer 512, and gate dielectric material 510 are patterned, and the manufacturing process is continued to form transistors 520 and 522 as shown in FIG. 16.

The third metal layer 578 is also referred to herein as a cap layer or as a second cap layer (e.g., when the second metal layer 574 comprises a first cap layer). The third metal layer 578 preferably comprises a material that is different than the material of the first metal layer 512 and the second metal layer 574. The third metal layer 578 preferably comprises a material that is adapted to alter the work function of the metal gate materials of the transistors 520 or 522. For example, the third metal layer 578 preferably comprises a material that is adapted to alter the work function of the metal gate materials of the transistors 520 or 522 that is established by the first metal layer 512 prior to the deposition of the third metal layer 578. Thus, in the embodiment shown in FIGS. 15 and 16, both the first metal layer 512 and the third metal layer 578 establish the threshold voltage of transistor 522. The first metal layer 512 and the second metal layer 574 establish the threshold voltage of transistor 520. In the embodiment shown in FIG. 17, the third metal layer 578, the second metal layer 574, and the first metal layer 512 establish the threshold voltage of transistor 520, and the third metal layer 578 and the first metal layer 512 establish the threshold voltage of transistor 522.

Note that the expression, “establishes the threshold voltage of the transistor” used herein refers to establishing a work function of the gate electrodes of the transistor, which establishes the threshold voltage of the transistor, by varying the materials and thicknesses of the first metal layer 512, the second metal layer 574, and the third metal layer 578 described herein.

In one embodiment, the third metal layer 578 preferably comprises TiN. In another embodiment, the third metal layer 578 preferably comprises TaCN. In other embodiments, the third metal layer 578 may comprise other metals adapted to alter the work function of the gate electrodes of the transistors 520 and 522, such as TiSiN, TiN, TaCN, TaN, Ta, Ru, HfN, W, Al, RuTa, TaSiN, NiSiₓ, CoSiₓ, TiSiₓ, Ir, Y, Pt, Ti, PtTi, Pd, Re, Rh, borides, phosphides, or antimonides of Ti, Hf, Zr, TiAlN, Mo, MoN, ZrSiN, ZrN, HfN, HfSiN, WN, Ni, Pr, VN, TiW, partially silicided materials thereof, fully silicided materials thereof, and/or combinations thereof, as examples, although alternatively, the third metal layer 578 may comprise other materials.

The third metal layer 578 preferably comprises a thickness of about 200 Angstroms or less, and more preferably comprises a thickness of about 50 to 100 Angstroms in some embodiments, although alternatively, the third metal layer 578 may comprise other dimensions, for example. The third metal layer 578 may comprise the same thickness as the second metal layer 574, or may comprise a different thickness than the second metal layer 574, for example. In a preferred embodiment, the third metal layer 578 comprises a thickness of about 100 Angstroms.

In some embodiments, it is advantageous to use a first metal layer 512 comprising a single thickness for the entire semiconductor device 500, and to use a second metal layer 574 and a third metal layer 578 comprising the same thickness. Lithography and dry etching processes may be improved by having a smooth top surface of the semiconductor device 500, for example.

The first metal layer 512, second metal layer 574, and the third metal layer 578 may be deposited by chemical vapor deposition (CVD), atomic layer deposition (ALD), metal organic chemical vapor deposition (MOCVD), physical vapor deposition (PVD), or jet vapor deposition (JVD), as examples, although alternatively, the metal layers 512, 574, and 578 may be deposited using other suitable deposition techniques.

Advantageously, the gate electrode of transistor 520 comprises the first metal layer 512 and the second metal layer 574, whereas the gate electrode of transistor 522 comprises the first metal layer 512 and the third metal layer 578 in this embodiment. Thus, the second metal layer 574 functions as a cap layer that is used to tune or alter the work function of the metal gate materials of the transistor 520, and the third metal layer 578 functions as a cap layer that is used to tune or alter the work function of the metal gate materials of the transistor 522, in this embodiment, e.g., to achieve desired threshold voltages of the transistors 520 and 522.

Again, as in the embodiment shown in FIGS. 13 and 14, the thickness of the first metal layer 512 may also be used as another variable, in combination with the use of the second metal layer 574 and the third metal layer 578 on transistor 520 and 522, respectively, wherein the thickness of the first metal layer 512 and the presence and/or the thickness of the second metal layer 574 and third metal layer 578 each comprise means of tuning or altering the work function of the metal gate materials of the transistors 520 and 522.

In one embodiment, wherein transistor 520 comprises a PMOS transistor, and wherein transistor 522 comprises an NMOS transistor, the first metal layer 512 preferably comprises TiSiN, the second metal layer 574 preferably comprises TaCN, and the third metal layer 578 preferably comprises TiN. These materials are suitable to produce a semiconductor device 500 wherein the PMOS transistor 520 and the NMOS transistor 522 comprise gate electrodes having work functions such that substantially symmetric threshold voltages of the PMOS transistor 520 and the NMOS transistor 522 are achieved, for example.

FIG. 17 shows a cross-sectional view of a semiconductor device 600 in accordance with a yet another preferred embodiment of the present invention. Like numerals are used in FIG. 17 that were used in FIGS. 13 through 16. In this embodiment, the third metal layer 678 is left remaining over the second metal layer 674 on transistor 620. The thickness and material of the third metal layer 678, second metal layer 674, and also the first metal layer 612 affect the work function of the metal gate materials of the transistor 620 and may be selected or chosen to tune the work function of the metal gate materials of the transistor 620, for example, e.g., to achieve symmetric threshold voltages for the transistors 620 and 622.

Note that in the embodiments shown in FIGS. 13 through 17, the gate electrodes of the transistors may also include a semiconductive material deposited over the metal layers 412, 474, 574, 578, and 678, as shown in FIG. 4 at 116.

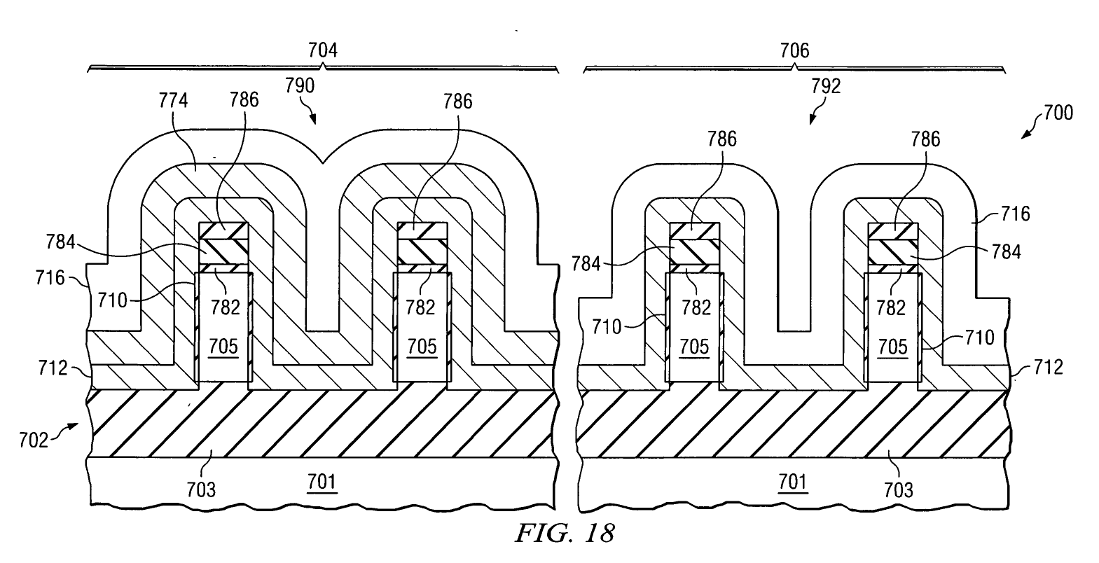

FIG. 18 shows a cross-sectional view of a semiconductor device 700 in accordance with another preferred embodiment of the present invention, implemented in a FinFET or multiple-gate device. In this embodiment, the semiconductor device 700 comprises a CMOS device comprising at least one multi-gate PMOS transistor 790 and at least one multi-gate NMOS transistor 792 wherein at least one of the gate electrodes 774/712 or 712 of the transistors 790 and 792, respectively, comprise a cap layer 774.

In this embodiment, the workpiece 702 preferably comprises a first layer of semiconductive material 701 that comprises a substrate, a buried insulating layer 703 or buried oxide layer disposed over the first layer of semiconductive material 701, and a second layer of semiconductive material 705 disposed over the buried insulating layer 703, for example. The workpiece 702 may comprise an SOI substrate, for example. The second layer of semiconductor material 705 may comprise silicon (Si) having a thickness of about 100 nm, for example, although alternatively, the second layer of semiconductor material 705 may comprise other materials and dimensions.

To fabricate the semiconductor device 700 shown in FIG. 18, a hard mask 782/784/786 is formed over the workpiece 102. The hard mask 782/784/786 comprises a first oxide layer 782 comprising about 5 nm or less of SiO₂ formed over the workpiece 702. A nitride layer 784 comprising about 20 nm of SiₓN_{y} is formed over the first oxide layer 782. A second oxide layer 786 comprising about 20 nm or less of SiO₂ is formed over the nitride layer 784. Alternatively, the hard mask 782/784/786 may comprise other materials and dimensions, for example.

The semiconductor device 700 includes at least one first region 704 wherein a PMOS device will be formed, and at least one second region 706 wherein an NMOS device will be formed, as shown. Only one first region 704 and one second region 706 are shown in FIG. 18; however, there may be many first regions 704 and second regions 706 formed on a semiconductor device 700, for example. The first region 704 and the second region 706 may be separated by isolation regions, not shown.

The hard mask 782/784/786 is patterned using lithography, e.g., by depositing a layer of photoresist over the hard mask 782/784/786, exposing the layer of photoresist to energy using a lithography mask, developing the layer of photoresist, and using the layer of photoresist as a mask to pattern the hard mask 782/784/786, for example. The hard mask 782/784/786, and optionally, also the layer of photoresist are used as a mask to pattern the second layer of semiconductive material 705 of the workpiece 702, as shown in FIG. 18. The buried insulating layer 703 may comprise an etch stop layer for the etch process of the second layer of semiconductive material 705, for example. A top portion of the buried insulating layer 703 may be removed during the etch process of the second layer of semiconductive material 701, as shown. For example, the buried insulating layer 703 may have a thickness of about 150 nm, and may be etched by an amount comprising about 15 nm or less, although alternatively, the buried insulating layer 703 may be etched by other amounts.

The second layer of semiconductor material 705 of the workpiece 702 forms vertical fins of semiconductor material 705 extending in a vertical direction away from a horizontal direction of the workpiece 702. The fin structures 705 will function as the channels of PMOS and NMOS devices. The fin structures 705 have a thickness (or height extending away from the buried insulating layer 703) that may comprise about 50 nm or less, as an example, although alternatively, the fins 705 may comprise other dimensions. For example, the thickness of the fin structures 705 may comprise about 5 to 60 nm, or less, in some applications. As another example, the thickness of the fin structures may be larger, such as about 100 to 1,000 nm. The thickness of the fin structures 705 may vary as a function of the channel doping and other dimensions of the fin structures 705, as examples.

The fin structures 705 have a height equivalent to the thickness of the second layer of semiconductor material 705, for example. Only two fin structures 705 are shown in region 704 and region 706 of the semiconductor device 700; however, there may be many fin structures, e.g., about 1 to 200 fin structures, for each PMOS and NMOS device, as examples, although alternatively, other numbers of fin structures 705 may be used.

A gate dielectric material 710 is formed over the sidewalls of the fins of semiconductor material 705, as shown in FIG. 18. The gate dielectric 710 may be formed using a thermal oxidation process, for example, wherein only the semiconductor material 705 is oxidized, as shown. Alternatively, the gate dielectric 710 may be formed using a deposition process, resulting in a thin layer of the gate dielectric 710 also being formed on the buried insulating layer 703 and the hard mask 782/784/786 (not shown), for example. The gate dielectric material 710 preferably comprises similar materials and thicknesses as described for gate dielectric material 410 shown in FIGS. 13 and 14, for example.

Next, a first metal layer 712 is formed over the fin structures 705 in regions 704 and 706. A second metal layer 774 is formed over the first metal layer 712 in region 704. The first metal layer 712 and the second metal layer 774 preferably comprise similar materials and dimensions as described for the first metal layer 412 and second metal layer 774 shown in FIGS. 13 and 14, for example. A third metal layer (not shown) may also be formed in region 706 in some embodiments, as described in the previous embodiments. Advantageously, the material and dimensions (or presence) of the second metal layer 774, first metal layer 712, and third metal layer, if included, control or establish the threshold voltage of the PMOS and NMOS transistors 790 and 792.

In region 704, the first metal layer 712 and the second metal layer 774 comprise a first gate electrode on a first sidewall of each fin of semiconductor material 705 and a second gate electrode on a second sidewall of each fin of semiconductor material 705 opposite the first sidewall. Thus, a FinFET having a dual gate electrode structure is formed on each fin of semiconductor material 705. Again, several fins 705 may be placed in parallel to form a PMOS device in the first region 704. In region 706, the first metal layer 712 comprises a first gate electrode on a first sidewall of each fin 705 and a second gate electrode on a second sidewall of each fin 705 opposing the first sidewall, forming an NMOS device in region 706, for example.

After depositing the second metal layer 774 and patterning it to remove at least a portion of the second metal layer 774 from region 706, an optional layer of semiconductive material 716 may be formed over the second metal layer 774 in region 704 and over the first metal layer 712 in region 706, as shown in FIG. 18. The layer of semiconductive material 716 may comprise polysilicon having a thickness of about 2,000 Angstroms or less, although alternatively, the layer of semiconductive material 716 may comprise other dimensions and materials, for example. The semiconductive material 716 comprises part of a gate electrode of the transistors formed in regions 704 and 706 of the workpiece 702, for example.

The manufacturing process for the semiconductor device 700 is then continued. For example, portions of the gate electrode material may be removed to form the gate electrodes for the CMOS FinFETs, e.g., the gate electrode material 774 and 712 and optional semiconductor material 716 are simultaneously patterned in region 704 and region 706 to form the gate electrodes of the PMOS and NMOS multiple gate transistors 790 and 792 in 704 and region 706, respectively. Additional insulating material layers may be formed over the gate electrodes. Contacts may be made to the source, drain, and gate electrodes of the FinFETs, for example, not shown.

Advantageously, a CMOS FinFET device 700 is formed, wherein a multiple gate PMOS transistor 790 in region 704 comprises a gate electrode 774/712 having a second metal layer 774 that establishes the threshold voltage of the PMOS transistors 790. The first metal layer 712 also establishes the threshold voltage of the NMOS transistors 792 in region 706. The gate electrode materials and thicknesses are selected to achieve a work function of the gate electrodes, which establishes the threshold voltages of the transistors 790 and 792, for example.

As described with reference to the embodiments in FIGS. 13 through 17, FinFET devices 700 may also be formed wherein the second metal layer 774 is also formed in region 706 but has a different thickness than in region 704. A third metal layer (not shown) may be formed over the first metal layer 712 in region 706, prior to depositing the optional semiconductive material 716. The third metal layer may also be formed over the second metal layer 774 in region 704, for example. The second and third metal layers function as cap layers adapted to tune the work function of the metal gate materials of transistors 790 and 792 so that a symmetric threshold voltage of the PMOS transistors 790 and NMOS transistors 792 may be achieved.

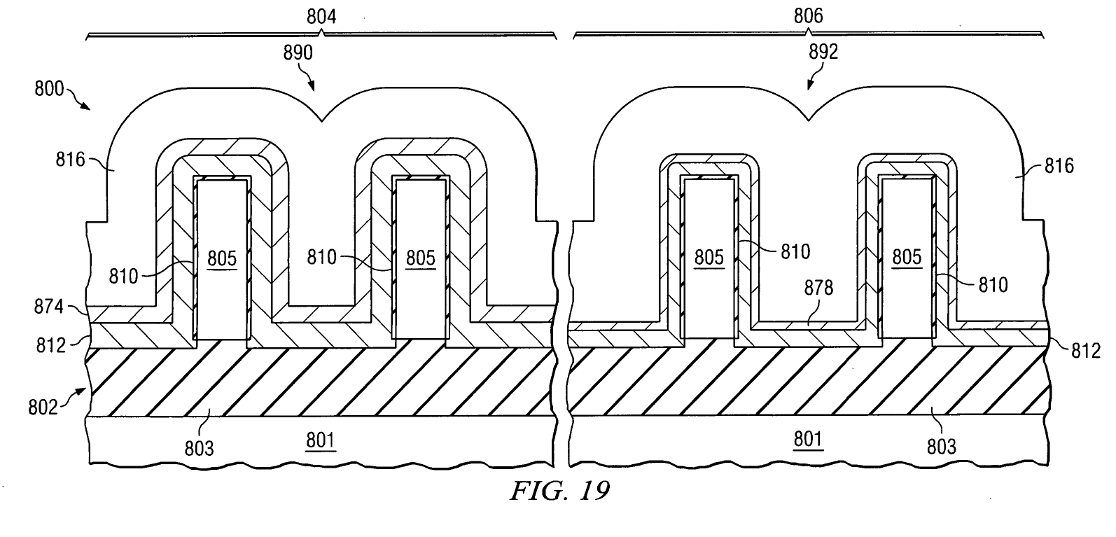

FIG. 19 shows a cross-sectional view an embodiment of the present invention implemented in a multiple gate device having three gates for each transistor. Like numerals are used for the elements in FIG. 19 as were used in FIG. 18 and the other figures. In this embodiment, a hard mask is not used over the top surface of the second layer of semiconductor material 805 of the SOI substrate 802, or alternatively, the hard mask is removed after the second layer of semiconductor material 805 is patterned to form the fin structures 805. In this embodiment, each transistor includes three first gate electrodes on a fin structure 805. A first gate electrode is disposed on a first sidewall of the fin structures 805, and a second gate electrode is disposed on a second sidewall of the fin structures 805, wherein the second sidewall opposes the first sidewall of the same fin structure 805. A third gate electrode is disposed on a top surface of each fin structure 805. The fin structures 805 function as channels of the transistors in regions 804 and 806, for example.

Transistors 890 comprise gate electrodes comprised of first metal layer 812, second metal layer 874, and semiconductive material layer 816. The material and thickness of the first metal layer 812, and the material and thickness of the second metal layer 874, establish the work function of the metal gate materials of the transistors 890 in region 804. Transistors 892 comprise gate electrodes comprised of first metal layer 812, third metal layer 878, and semiconductive material layer 816. The material and thickness of the first metal layer 812, and the material and thickness of the third metal layer 878, establish the work function of the metal gate materials of the transistors 892 in region 806.

In FIG. 19, the thickness of the first metal layer 812 in region 804 is greater than the thickness of the first metal layer 812 in region 806. The thickness of the second metal layer 874 in region 804 is also greater than the thickness of the third metal layer 878 in region 806. These thickness variations illustrate another means of tuning or adjusting the work function of the gate electrodes of transistors 890 and 892 in accordance with embodiments of the present invention. However, alternatively, the first metal layer 812 may comprise substantially the same thickness in both regions 804 and 806, and the second metal layer 874 and the third metal layer 878 may comprise substantially the same thickness in regions 804 and 806, respectively, for example.

Processing of the semiconductor device is then continued. For example, portions of the fin structures 805 may be implanted with dopants to form source and drain regions. The implantation steps to form the source and drain regions may alternatively take place before the manufacturing process steps described herein, in some embodiments, for example. After patterning the material layers 816, 874, 878, and 812 to form the gate electrodes of the transistors 890 and 892, spacers comprising an insulating material such as an oxide, nitride, or combinations thereof, may be formed over the sidewalls of the gate electrodes (and hard mask 782, 784, 786, if included, shown in FIG. 18).

In some embodiments, the second metal layers 474, 574, 674, 774, and 874 and/or third metal layers 578, 678, and 878 described herein cause the gate material of PMOS transistors 420, 520, 620, 790, and 890 to have a work function of about 4.85 eV, and causes the gate material of the NMOS transistors 422, 522, 622, 792, and 892 to have a work function of about 4.45 eV. In other embodiments, the work function of the gate electrode of the PMOS transistors 420, 520, 620, 790, and 890 preferably comprises about 4.5 to 4.9 eV, and the work function of the gate electrode of the NMOS transistors 422, 522, 622, 792, and 892 preferably comprises about 4.2 to 4.6 eV, for example. The PMOS transistors 420, 520, 620, 790, and 890 and the NMOS transistors 422, 522, 622, 792, and 892 preferably have substantially symmetric threshold voltages of about +0.3 and −0.3 V, respectively, as examples, in one embodiment, although the threshold voltages may alternatively comprise other voltage levels, such as symmetric threshold voltages Vₜ values of about +/−0.1 V to about +/−15 V, as examples.

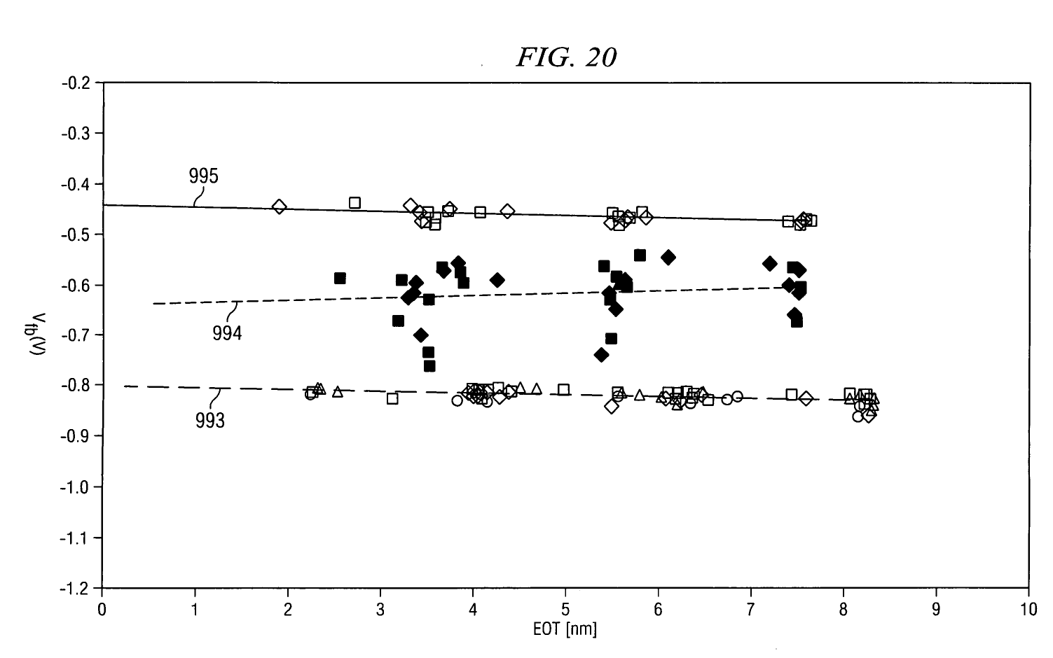

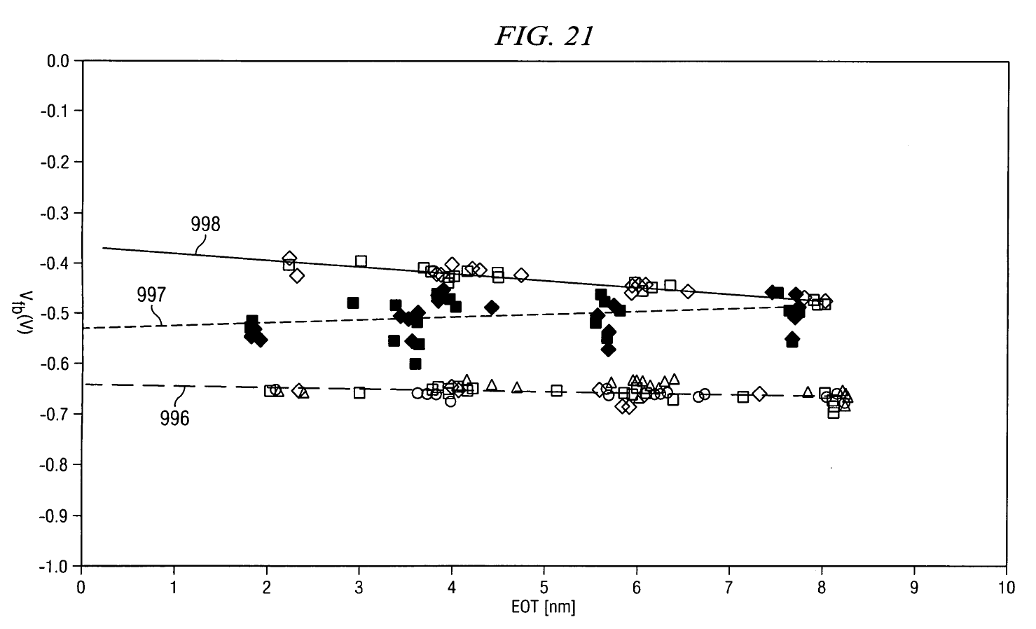

FIGS. 20 and 21 are graphs illustrating experimental test results of flat band voltage (V_{fb}) in volts (V) versus effective oxide thickness (EOT) at various test conditions for embodiments of the present invention, with and without the novel cap layers 474, 574, 674, 774, 874, 578, 678, and 878 described herein, illustrating that the cap layers 474, 574, 674, 774, 874, 578, 678, and 878 are effective in tuning the work function of gate electrode materials of PMOS and NMOS transistors of a CMOS device. Test results are shown in FIG. 20 for devices having a gate dielectric material comprising SiO₂. For example, in the graph at 993, test results are shown for NMOS devices having a gate electrode comprised of 25 Angstroms of TiSiN without a cap layer. The work function was found to be 4.28 eV, and the charge density N_{f} was found to be 7.21×10¹⁰/cm². At 994, test results are shown for NMOS devices having a gate electrode comprised of 25 Angstroms of TiSiN and a cap layer comprising 200 Angstroms of TiN. The work function was found to be 4.44 eV, and the charge density N_{f} was found to be −9.93×10¹⁰/cm². At 995, test results are shown for NMOS devices having a gate electrode comprised of 25 Angstroms of TiSiN and a cap layer comprising 100 Angstroms of TaCN. The work function was found to be 4.63 eV, and the charge density N_{f} was found to be 8.79×10¹⁰/cm². Thus, a 200 Angstroms thick cap layer of TiN increased the work function by about 0.16 eV, and a 100 Angstroms thick cap layer of TaCN increased the work function by about 0.35 eV.

FIG. 21 shows a similar plot for test results using HfSiOₓ as a gate dielectric material. For example, in the graph at 996, test results are shown for NMOS devices having a gate electrode comprised of 25 Angstroms of TiSiN without a cap layer. The work function was found to be 4.44 eV, and the charge density N_{f} was found to be 5.49×10¹⁰/cm². At 997, test results are shown for NMOS devices having a gate electrode comprised of 25 Angstroms of TiSiN and a cap layer comprising 200 Angstroms of TiN. The work function was found to be 4.55 eV, and the charge density N_{f} was found to be −1.16×10¹¹/cm². At 998, test results are shown for NMOS devices having a gate electrode comprised of 25 Angstroms of TiSiN and a cap layer comprising 100 Angstroms of TaCN. The work function was found to be 4.71 eV, and the charge density N_{f} was found to be 2.80×10¹¹/cm². Thus, a 200 Angstroms thick cap layer of TiN increased the work function by about 0.11 eV, and a 100 Angstroms thick cap layer of TaCN increased the work function by about 0.27 eV.

Embodiments of the present invention achieve technical advantages in several different device applications. For example, embodiments of the invention may be implemented in NMOS high performance (HP) devices, NMOS low operation power (LOP) devices, NMOS Low Standby Power (LSTP) devices, PMOS high performance devices, PMOS low operation power devices, and PMOS Low Standby Power devices, as examples. The parameters for these HP devices, LOP devices, and LSTP devices, are defined in the 2002 edition of International Technology Roadmap for Semiconductors (ITRS), incorporated herein by reference. Preferably, in accordance with embodiments of the present invention, all devices of one type (e.g., either NMOS or PMOS) will have the same implantation doping levels, e.g., for forming source and drain regions of transistors, but may have different gate electrode layer thicknesses, and cap layers, or may not have cap layers, according to the type of device, e.g., HP, LOP, or LSTP. Additional implantation processes are optional, but are not necessary, for example.

In one embodiment, a first transistor may comprise a first CMOS device, and a second transistor may comprise a second CMOS device, wherein the first CMOS device comprises a first device type, and wherein the second CMOS device comprises a second device type. The second device type is preferably different from the first device type. For example, the first device type and/or the second device type may comprise a high performance (HP) device, a low operation power (LOP) device, or a low standby power (LSTP) device, for example.

Thus, novel semiconductor devices 100, 200, 400, 500, 600, 700, and 800 comprising CMOS devices having PMOS and NMOS devices comprising a metal gate electrode are formed in accordance with embodiments of the present invention. Advantages of preferred embodiments of the present invention include providing methods of fabricating semiconductor devices 100, 200, 400, 500, 600, 700, and 800 and structures thereof. The PMOS and NMOS transistors have a substantially symmetric threshold voltage Vₜ. For example, Vₜₚ is preferably about −0.3 V, and Vₜₙ may be the substantially the same positive value, e.g., about +0.3 V. The novel cap layers 474, 574, 674, 774, 874, 578, 678, and 878 may be used to tune and adjust the work function of the gates of transistors to achieve a desired threshold voltage, such as a symmetric threshold voltage for PMOS and NMOS transistors in a CMOS device, for example. The cap layer 474, 574, 674, 774, 874, 578, 678, and 878 material and thickness (e.g., of the second metal layers 474, 574, 674, and 774 and the third metal layers 578, 678, and 878), and the material and thickness of the first metal layers 412, 512, 612, 712, and 812 set the work function of the gate electrodes of the transistors, for example.

Although embodiments of the present invention and their advantages have been described in detail, it should be understood that various changes, substitutions and alterations can be made herein without departing from the spirit and scope of the invention as defined by the appended claims. For example, it will be readily understood by those skilled in the art that many of the features, functions, processes, and materials described herein may be varied while remaining within the scope of the present invention. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A semiconductor device, comprising:
a first transistor, the first transistor comprising at least one first gate electrode including a first metal layer; and
a second transistor, the second transistor comprising at least one second gate electrode including the first metal layer, wherein the at least one first gate electrode or the at least one second gate electrode includes a second metal layer disposed over the first metal layer.

2. The semiconductor device according to claim 1, wherein the second metal layer comprises a cap layer that affects a work function of the at least one first gate electrode of the first transistor or the at least one second gate electrode of the second transistor.

3. The semiconductor device according to claim 1, wherein the second metal layer comprises a different material than the first metal layer.

4. The semiconductor device according to claim 3, wherein the first metal layer and the second metal layer comprise TiSiN, TiN, TaCN, TaN, Ta, Ru, HfN, W, Al, RuTa, TaSiN, NiSi, CoSiₓ, TiSiₓ, Ir, Y, Pt, Ti, PtTi, Pd, Re, Rh, borides, phosphides, or antimonides of Ti, Hf, Zr, TiAlN, Mo, MoN, ZrSiN, ZrN, HfN, HfSiN, WN, Ni, Pr, VN, TiW, partially silicided materials thereof, fully silicided materials thereof, and/or combinations thereof.

5. The semiconductor device according to claim 1, wherein the first metal layer comprises TiSiN, and wherein the second metal layer comprises TaCN or TiN.

6. The semiconductor device according to claim 1, wherein the first metal layer of the at least one first gate electrode of the first transistor comprises the same thickness or a different thickness than the first metal layer of the at least one second gate electrode of the second transistor.

7. A semiconductor device, comprising:
a first transistor, the first transistor comprising at least one first gate electrode including a first metal layer and a second metal layer disposed over the first metal layer; and
a second transistor, the second transistor comprising at least one second gate electrode including the first metal layer and a third metal layer disposed over the first metal layer, wherein the third metal layer comprises a different material than the second metal layer.

8. The semiconductor device according to claim 7, wherein the second metal layer comprises a first cap layer that affects a first work function of the at least one first gate electrode of the first transistor, and wherein the third metal layer comprises a second cap layer that affects a second work function of the at least one second gate electrode of the second transistor.

9. The semiconductor device according to claim 7, wherein the first metal layer, the second metal layer, and the third metal layer comprise a thickness of about 200 Angstroms or less.

10. The semiconductor device according to claim 7, wherein the at least one first gate electrode and the at least one second gate electrode include a layer of semiconductive material disposed over the second metal layer and third metal layer, respectively.

11. The semiconductor device according to claim 7, wherein the first transistor comprises a single gate electrode or multiple gate electrodes, and wherein the second transistor comprises a single gate electrode or multiple gate electrodes.

12. The semiconductor device according to claim 7, wherein the second metal layer and the third metal layer comprise the same thickness or different thicknesses.

13. A semiconductor device, comprising:
a positive channel metal oxide semiconductor (PMOS) transistor, the PMOS transistor comprising at least one first gate electrode including a first metal layer and a second metal layer disposed over the first metal layer, the second metal layer comprising a different material than the first metal layer; and
a negative channel metal oxide semiconductor (NMOS) transistor, the NMOS transistor comprising at least one second gate electrode including the first metal layer and a third metal layer disposed over the first metal layer, the third metal layer comprising a different material than the second metal layer and the first metal layer.

14. The semiconductor device according to claim 13, wherein the second metal layer comprises a first cap layer that affects a first work function of the at least one first gate electrode of the PMOS transistor, wherein the third metal layer comprises a second cap layer that affects a second work function of the at least one second gate electrode of the NMOS transistor, wherein the first work function comprises about 4.5 to 4.9 eV, and wherein the second work function comprises about 4.2 to 4.6 eV.

15. The semiconductor device according to claim 13, wherein the PMOS transistor and the NMOS transistor comprise symmetric threshold voltage Vₜ values of about +/−0.1 V to about +/−15V.

16. The semiconductor device according to claim 13, wherein the PMOS transistor and the NMOS transistor include a gate dielectric material disposed beneath the first metal layer, wherein the gate dielectric material comprises a hafnium-based dielectric, HfO₂, HfSiOₓ, Al₂O₃, ZrO₂, ZrSiOₓ, Ta₂O₅, La₂O₃, nitrides thereof, SiₓN_{y}, SiON, HfAlOₓ, HfAlOₓN_{1-x-y}, ZrAlOₓ, ZrAlOₓN_{y}, SiAlO_{y}, SiAlOₓN_{1-x-y}, HfSiAlOₓ, HfSiAlOₓN_{y}, ZrSiAlOₓ, ZrSiAlOₓN_{y}, combinations thereof, combinations thereof with SiO₂, or SiO₂.

17. A method of manufacturing a semiconductor device, the method comprising:
providing a workpiece, the workpiece having a first region and a second region;
forming a gate dielectric material over the workpiece;
forming a first metal layer over the gate dielectric material;
forming a second metal layer over the first metal layer;
removing at least a portion of the second metal layer in the second region; and
patterning the second metal layer, the first metal layer, and the gate dielectric material to form a first transistor in the first region and a second transistor in the second region.

18. The method according to claim 17, wherein removing at least a portion of the second metal layer in the second region comprises reducing the thickness of the second metal layer in the second region.

19. The method according to claim 17, wherein removing at least a portion of the second metal layer in the second region comprises removing all of the second metal layer in the second region.

20. The method according to claim 19, further comprising forming a third metal layer over the second metal layer in the first region and over the first metal layer in the second region, wherein patterning the second metal layer, the first metal layer and the gate dielectric material further comprises patterning the third metal layer.

21. The method according to claim 20, further comprising removing at least a portion of the third metal layer from over the second metal layer in the first region.

22. The method according to claim 21, wherein removing at least a portion of the third metal layer from over the second metal layer in the first region comprises removing all of the third metal layer from over the second metal layer in the first region.

23. The method according to claim 21, wherein removing at least a portion of the third metal layer from over the second metal layer in the first region comprises reducing the thickness of the third metal layer in the first region.

24. The method according to claim 17, wherein the first transistor comprises a first CMOS device, wherein the second transistor comprises a second CMOS device, wherein the first CMOS device comprises a first device type, wherein the second CMOS device comprises a second device type, wherein the second device type is different from the first device type, and wherein the first device type and the second device type comprise a high performance (HP) device, a low operation power (LOP) device, or a low standby power (LSTP) device.

25. The method according to claim 17, wherein providing the workpiece comprises providing a silicon-on-insulator (SOI) substrate having a substrate, a buried insulating layer disposed over the substrate, and a layer of semiconductor material disposed over the buried insulating layer, further comprising, before forming the gate dielectric material over the workpiece:
forming at least one first fin structure and at least one second fin structure within the layer of semiconductor material disposed over the buried insulating layer of the SOI substrate within the first region and second region of the workpiece, respectively, each of the at least one first fin structure and each of the at least one second fin structure comprising a first sidewall and an opposing second sidewall, wherein forming the gate dielectric material comprises forming the gate dielectric material over at least the first and second sidewalls of the at least one first fin structure and the at least one second fin structure, wherein patterning the second metal layer, the first metal layer, and the gate dielectric material comprising forming at least two first gate electrodes in the first region and forming at least two second gate electrodes in the second region, wherein the at least two first gate electrodes, the gate dielectric material, and the at least one first fin structure comprise the first transistor, and wherein the at least two second gate electrodes, the gate dielectric material, and the at least one second fin structure comprise the second transistor.

26. The method according to claim 25, wherein patterning the second metal layer, the first metal layer, and the gate dielectric material comprise forming a plurality of first transistors in the first region and a plurality of second transistors in the second region.
